(19) United States
(12) Patent Application Publication
(10) Pub. No.: US 2009/0267495 A1
(43) Pub. Date: Oct. 29, 2009

(54) ORGANIC LIGHT EMITTING DEVICE AND MANUFACTURING METHOD THEREOF

(76) Inventors: Jae-Hoon Jung, Suwon-si (KR); Joon-Hoo Choi, Seoul (KR)

Correspondence Address: Haynes and Boone, LLP;IP Section, 2323 Victory Avenue, SUITE 700, Dallas, TX, 75219, US

(21) Appl. No.: 12/331,146

(22) Filed: Dec. 9, 2008

(30) Foreign Application Priority Data
Apr. 23, 2008 (KR) 10-2008-0037777

(51) Int. Cl. H01J 1/62; H01L 51/56

(52) U.S. Cl. 313/504; 438/29; 257/E51.001

(57) ABSTRACT

The present invention provides an organic light emitting device and a manufacturing method thereof. An organic light emitting device in accordance with an exemplary embodiment of the present invention includes: a thin film structure formed on a substrate; a first color filter formed on the thin film structure; a first insulating layer formed on the first color filter; a first transflective metal member formed on the first insulating layer and positioned on the first color filter; a second insulating layer formed on the first transflective metal member; a first transparent electrode formed on the second insulating layer and positioned on the first transflective metal member; a first pixel electrode formed on the first transparent electrode; a white organic light emitting member formed on the first pixel electrode; and a common electrode formed on the white organic light emitting member.

### CROSS-REFERENCE TO RELATED APPLICATION

This application claims priority to and the benefit of Korean Patent Application No. 10-2008-0037777 filed in the Korean Intellectual Property Office on Apr. 23, 2008, the entire contents of which are incorporated herein by reference.

### BACKGROUND OF THE INVENTION

(a) Field of the Invention

The present invention relates to an organic light emitting device and a manufacturing method thereof.

(b) Description of the Related Art

An organic light emitting device includes a plurality of pixels, and each pixel includes an organic light emitting element and a plurality of thin film transistors for driving the same.

The organic light emitting element includes an anode, a cathode, and an organic light emitting member disposed therebetween. The organic light emitting member emits light of three primary colors such as red, green, and blue, or white light. A material used for an organic light emitting member depends on the color that the organic light emitting member emits. A white light can be generated usually by stacking light emitting materials that emit red, green, and blue so that the synthesized light becomes white. Moreover, in the case where the organic light emitting member emits white light, a color filter is added to obtain light of a desired color.

However, light emitted from the respective pixels may not have desired optical characteristics such as wavelength and color purity due to material characteristics of the organic light emitting element or due to light interference by a thin film through which light passes.

### SUMMARY OF THE INVENTION

The present invention has been made in an effort to provide an organic light emitting device and a manufacturing method thereof. An exemplary embodiment of the present invention provides an organic light emitting device including: a thin film structure disposed on a substrate; a first color filter disposed on the thin film structure; a first insulating layer disposed on the first color filter; a first transflective metal member disposed on the first insulating layer and positioned on the first color filter; a second insulating layer disposed on the first transflective metal member; a first transparent electrode disposed on the second insulating layer and positioned on the first transflective metal member; a first pixel electrode disposed on the first transparent electrode; a white organic light emitting member disposed on the first pixel electrode; and a common electrode disposed on the white organic light emitting member.

The first transflective metal member may include silver or aluminum, and may have a thickness of 50 Å to 200 Å.

The organic light emitting device may further include a first conductive oxide member formed between the first insulating layer and the first transflective metal member.

The first conductive oxide member may include indium tin oxide (ITO) or indium zinc oxide (IZO), and may have a thickness of 50 Å to 500 Å.

The second insulating layer may include an inorganic material such as silicon oxide or silicon nitride, and may have a thickness of 500 Å to 3000 Å.

The first transparent electrode may include indium tin oxide (ITO) or indium zinc oxide (IZO) and may have a thickness of 300 Å to 3000 Å.

The organic light emitting device may further include a first conductive oxide member formed between the first insulating layer and the first transflective metal member.

The first insulating layer may include an organic material and the second insulating layer may include an inorganic material.

The organic light emitting device may further include a second color filter formed between the thin film structure and the first insulating layer, a second transflective metal member formed between the first insulating layer and the second insulating layer and positioned on the second color filter, and a second pixel electrode formed between the second insulating layer and the white organic light emitting member, being in contact with the second insulating layer, and positioned on the first transflective metal member.

The organic light emitting device may further include a second conductive oxide member formed between the first insulating layer and the second transflective metal member.

The organic light emitting device may further include a third pixel electrode formed between the second insulating layer and the white organic light emitting member and being in contact with the second insulating layer, in which a portion of the first insulating layer positioned at the bottom of the third pixel electrode may be in contact with the thin film structure, and a portion of the second insulating layer positioned at the bottom of the third pixel electrode may be in contact with the first insulating layer.

Another embodiment of the present invention provides an organic light emitting device including: a substrate including a first region, a second region, and a third region; a thin film structure disposed on the substrate; first, second, and third color filters disposed on the thin film structure and positioned in the first, second, and third regions, respectively; a first insulating layer disposed on the first to third color filters; first, second, and third transflective metal members disposed on the first insulating layer and positioned in the first, second, and third regions, respectively; a second insulating layer disposed on the first to third transflective metal members; first and second transparent electrodes disposed on the second insulating layer and positioned in the first and second regions, respectively; first and second pixel electrodes disposed on the first and second transparent electrodes, respectively; a third pixel electrode disposed on the second insulating layer, positioned in the third region, and being in contact with the second insulating layer; a white organic light emitting member disposed on the first to third pixel electrodes; and a common electrode disposed on the white organic light emitting member.

The first transflective metal member may include silver or aluminum.

The first insulating layer may include an organic material and the second insulating layer may include an inorganic material.

The substrate may further include a fourth region, the organic light emitting device may further include a fourth pixel electrode formed between the second insulating layer and the white organic light emitting member and positioned in the fourth region, the first insulating layer may be in contact with the thin film structure in the fourth region, and the second insulating layer may be in contact with the fourth pixel electrode and the first insulating layer in the fourth region.

The first color filter may display red, the second color filter may display blue, and the third color filter may display green.

Yet another embodiment of the present invention provides a method of manufacturing an organic light emitting device, the method including: forming a thin film structure on a substrate including a first region, a second region, and a third region; forming first, second, and third color filters in the first, second, and third regions on the thin film structure, respectively; forming a first insulating layer on the first to third color filters; forming first, second, and third transflective metal members in the first, second, and third regions on the first insulating layer, respectively; forming a second insulating layer on the first to third transflective metal members; forming first and second transparent electrodes in the first and second regions on the second insulating layer, respectively; forming first and second pixel electrodes on the first and second transparent electrodes, respectively, and simultaneously forming a third pixel electrode being in contact with the second insulating layer in the third region on the second insulating layer; forming a white organic light emitting member on the first to third pixel electrodes; and forming a common electrode on the white organic light emitting member.

### BRIEF DESCRIPTION OF THE DRAWINGS

FIG. 1 is an equivalent circuit diagram of an organic light emitting device in accordance with an exemplary embodiment of the present invention;

FIG. 2 is a cross-sectional view of the organic light emitting device in accordance with the exemplary embodiment of the present invention;

FIGS. 3 to 9 are cross-sectional views of a structure formed in intermediate steps of manufacturing the organic light emitting device of FIG. 2;

FIG. 10 is a layout view of the organic light emitting device in accordance with the exemplary embodiment of the present invention; and

FIG. 11 is a cross-sectional view of the organic light emitting device taken along line XI-XI of FIG. 10.

### DETAILED DESCRIPTION OF THE EMBODIMENTS

Hereinafter, the present invention will be described more fully with reference to the accompanying drawings, in which exemplary embodiments of the invention are shown.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

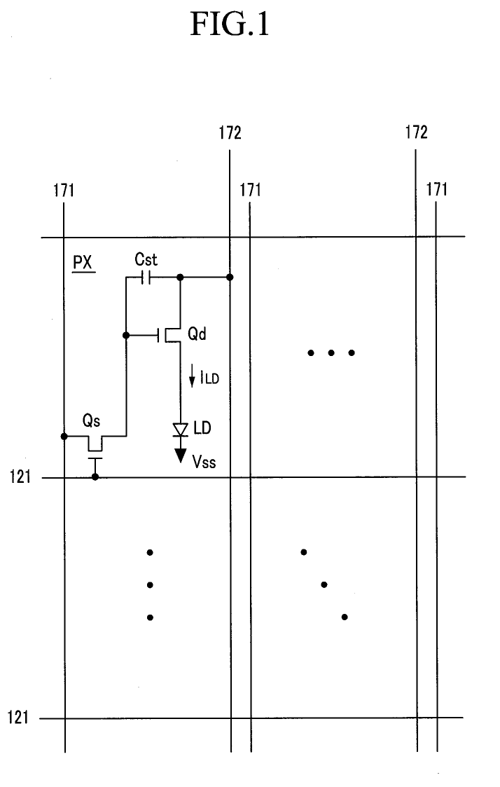

First, an organic light emitting device in accordance with an exemplary embodiment of the present invention will be described with reference to FIG. 1.

FIG. 1 is an equivalent circuit diagram of an organic light emitting device in accordance with an exemplary embodiment of the present invention.

Referring to FIG. 1, the organic light emitting device in accordance with the present exemplary embodiment includes a plurality of signal lines 121, 171, and 172, and a plurality of pixels PX connected to the signal lines 121, 171, and 172 and arranged in a matrix.

The signal lines includes a plurality of gate lines 121 for transmitting gate signals (or scanning signals), a plurality of data lines 171 for transmitting data signals, and a plurality of driving voltage lines 172 for transmitting driving voltages. The gate lines 121 extends substantially in a row direction and are substantially parallel to each other, and the data lines 171 extends substantially in a column direction and are substantially parallel to each other. Although the driving voltage lines 172 are shown as extending substantially in a column direction, they may extend in a row direction or in a column direction, or may be formed in a matrix.

Each pixel PX includes a switching transistor Qs, a driving transistor Qd, a storage capacitor Cst, and an organic light emitting element LD.

The switching transistor Qs includes a control terminal, an input terminal, and an output terminal. The control terminal is connected to a gate line 121, the input terminal is connected to a data line 171, and the output terminal is connected to the driving transistor Qd. The switching transistor Qs transmits a data signal received from the data line 171 to the driving transistor Qd in response to a scanning signal received from the gate line 121.

The driving transistor Qd also includes a control terminal, an input terminal, and an output terminal. The control terminal is connected to the switching transistor Qs, the input terminal is connected to a driving voltage line 172, and the output terminal is connected to the organic light emitting element LD. The driving transistor Qd applies an output current I_{LD} having a magnitude that varies according to a voltage difference between the control terminal and the output terminal.

The capacitor Cst is connected between the control terminal and the input terminal of the driving transistor Qd. The capacitor Cst stores the data signal applied to the control terminal of the driving transistor Qd and maintains the stored data signal even after the switching transistor Qs is turned off.

The organic light emitting element LD, which is an organic light emitting diode (OLED), for example, has an anode connected to the output terminal of the driving transistor Qd and a cathode connected to a common voltage Vss. The organic light emitting element LD emits light having an intensity that depends on the output current I_{LD} of the driving transistor Qd, to display an image.

The switching transistor Qs and the driving transistor Qd are n-channel field effect transistors (FET); however, at least one of the switching transistor Qs and the driving transistor Qd may be a p-channel FET. Moreover, the connection relationship among the transistors Qs and Qd, the storage capacitor Cst, and the organic light emitting element LD may be changed.

If necessary, transistors for compensating a threshold voltage of the driving transistor Qd and the organic light emitting element LD may be further provided in addition to the switching transistor Qs and the driving transistor Qd.

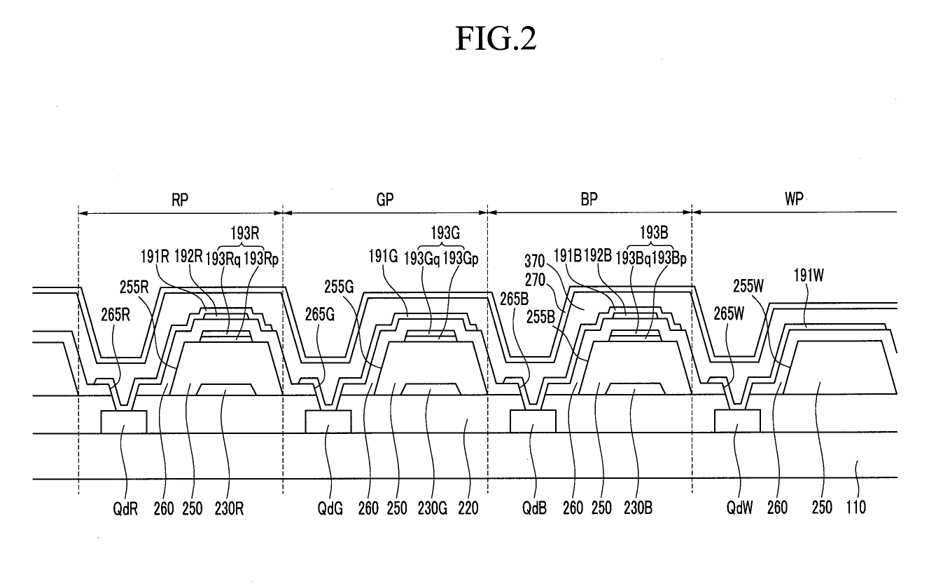

Next, the structure of the organic light emitting device shown in FIG. 1 will be described in detail with reference to FIG. 2.

FIG. 2 is a cross-sectional view of the organic light emitting device in accordance with the exemplary embodiment of the present invention.

The organic light emitting device in accordance with the present exemplary embodiment includes a red pixel RP, a green pixel GP, a blue pixel BP, and a white pixel WP. The white pixel WP is provided to improve luminance, and may be eliminated. Moreover, pixels representing three primary colors other than red, green, and blue may be included.

In FIG. 2, R, G, B, and W are added to the reference numerals related to the red pixel RP, the green pixel GP, the blue pixel BP, and the white pixel WP, respectively.

A plurality of driving transistors QdR, QdG, QdB, and QdW are formed on an insulation substrate 110 that may be made of transparent glass or plastic. Moreover, a thin film structure 220 including switching transistors is formed on the substrate 110. The thin film structure 220 may include an insulating layer for covering the driving transistors QdR, QdG, QdB, and QdW, and another thin film structure may be formed below the driving transistors QdR, QdG, QdB, and QdW.

A red color filter 230R, a green color filter 230G, and a blue color filter 230B are formed on the thin film structure 220. The white pixel WP includes no color filter.

An overcoat 250 is formed on the color filters 230R, 230G, and 230B and the thin film structure 220. Since the white pixel WP includes no color filter, the overcoat 250 in this region is in contact with the thin film structure 220.

The overcoat 250 may be made of an organic material and may have a flat surface. A plurality of through holes 255R, 255G, 255B, and 255W positioned on the driving transistors QdR, QdG, QdB, and QdW are formed on the overcoat 250.

Translucent members 193R, 193G and 193B are formed on the overcoat 250. The transflective members 193R, 193G, and 193B are positioned on the color filters 230R, 230G, and 230B, and the white pixel WP includes no transflective member.

Each of the transflective members 193R, 193G, and 193B includes a conductive oxide member 193Rp, 193Gp, or 193Bp that may be made of a metal oxide and a transflective metal member 193Rq, 193Gq, or 193Bq that may be made of a metal.

The transflective metal members 193Rq, 193Gq, and 193Bq may be made of a metal having high reflectance such as silver (Ag) or aluminum (Al), and may have a thickness of about 150 Å to about 200 Å. In this way, a small thickness of a metal film makes the metal film have transflective characteristics in which incident light may be reflected or transmitted.

The conductive oxide members 193Rp, 193Gp, and 193Bp are positioned between the transflective metal members 193Rq, 193Gq, and 193Bq and the overcoat 250. The conductive oxide members 193Rp, 193Gp, and 193Bp may be made of indium tin oxide (ITO) or indium zinc oxide (IZO), and may have a thickness of about 50 Å to about 500 Å. The conductive oxide members 193Rp, 193Gp, and 193Bp protect the transflective metal members 193Rq, 193Gq, and 193Bq from oxygen or moisture that may leak from the overcoat 250 formed of an organic material.

An insulating layer 260 is formed on the transflective members 193R, 193G, and 193B and the overcoat 250. Since the white pixel WP includes no transflective member, the insulating layer 260 is in contact with the overcoat 250 in this region.

The insulating layer 260 may be made of an inorganic material such as silicon oxide (SiOx) or silicon nitride (SiNx), and may have a thickness of about 500 Å to about 3000 Å. The insulating layer 260 prevents the transflective metal members 193Rq, 193Gq, and 193Bq from being oxidized.

A plurality of contact holes 265R, 265G, 265B, and 265W, penetrating the through holes 255R, 255G, 255B, and 255W of the overcoat 250 and exposing portions of the driving transistors QdR, QdG, QdB, and QdW, are formed on the insulating layer 260 and the thin film structure 220.

A plurality of transparent electrodes 192R and 192B are formed on the insulating layer 260. The green pixel GP and the white pixel WP include no transparent electrode.

The transparent electrodes 192R and 192B may be made of ITO or IZO, and may have a thickness of about 300 Å to about 3000 Å.

A plurality of pixel electrodes 191R, 191G, 191B, and 191W are formed on the transparent electrodes 192R and 192B and the insulating layer 260. Since the green pixel GP and the white pixel WP include no transparent electrode, the pixel electrodes 191G and 191W in these regions are in contact with the insulating layer 260.

The pixel electrodes 191R, 191G, 191B, and 191W are connected to the driving transistors QdR, QdG, QdB, and QdW through the contact holes 265R, 265G, 265B, and 265W. The pixel electrodes 191R, 191G, 191B and 191W may be made of ITO or IZO and may have a thickness of about 300 Å to about 3000 Å.

A white organic light emitting member 370 is formed on the pixel electrodes 191R, 191G, 191B, and 191W and the insulating layer 260, and a common electrode 270 for transmitting a common voltage Vss is formed thereon.

The white organic light emitting member 370 may have a multilayered structure including a plurality of organic material layers for emitting light of different colors, and the common electrode 270 may be made of a reflective metal including calcium (Ca), barium (Ba), magnesium (Mg), aluminum, silver (Ag), etc.

In the above-described organic light emitting device, the pixel electrodes 191R, 191G, 191B, and 191W, the white organic light emitting member 370, and the common electrode 270 form the organic light emitting element LD, in which the pixel electrodes 191R, 191G, 191B, and 191W form the anode and the common electrode 270 forms the cathode.

The organic light emitting device emits light toward the bottom of the substrate 110 to display an image. Except for the white pixel WP, light emitted from the white organic light emitting member 370 toward the substrate 110 passes through the pixel electrodes 191R, 191G, and 191B, the transparent electrodes 192R and 192B (but not the green pixel GP), and the insulating layer 260, and reaches the transflective metal members 193Rq, 193Gq, and 193Bq. The transfiective metal members 193Rq, 193Gq, and 193Bq reflect the incident light toward the common electrode 270, and the common electrode 270 reflects the same back to the transflective metal members 193Rq, 193Gq, and 193Bq. In this way, the light reciprocating between the transflective metal members 193Rq, 193Gq, and 193Bq and the common electrode 270 is subjected to an optical process such as interference and then passes through the transflective metal members 193Rq, 193Gq, and 193Bq and the color filters 230R, 230G, and 230B to the outside when appropriate conditions are satisfied.

In this case, since the light path varies depending on, for example, the thicknesses and refractive indexes of thin films interposed between the transflective metal members 193Rq, 193Gq, and 193Bq and the common electrode 270, it is possible to obtain light having desired optical characteristics such as wavelengths within a desired range and color purity, when the thicknesses and materials of the thin films are appropriately selected.

Particularly, in the case where the transflective members 193R, 193G, and 193B are formed of metal thin films in accordance with the present exemplary embodiment, the deviation of the thickness is small, and thus the deviation of the desired optical characteristics, e.g., the color purity, is small. On the contrary, in the case where the transflective members 193R, 193G, and 193B are formed of insulating layers, instead of the metal thin films, the thickness thereof may be greater than that in the former case, and thus the deviation of the thickness is increased such that the deviation of the optical characteristics is increased.

However, if the thickness of the transflective metal members 193Rq, 193Gq, and 193Bq is too large, the luminance of emitted light may be reduced, whereas if it is too small, it is difficult to obtain the desired optical characteristics. Accordingly, the thickness may be in the range of about 50 Å-about 200 Å as described above.

The thickness of the transparent electrodes 192R and 192B is determined in consideration of the desired optical characteristics, and the green pixel GP has no transparent electrode to enhance the color purity.

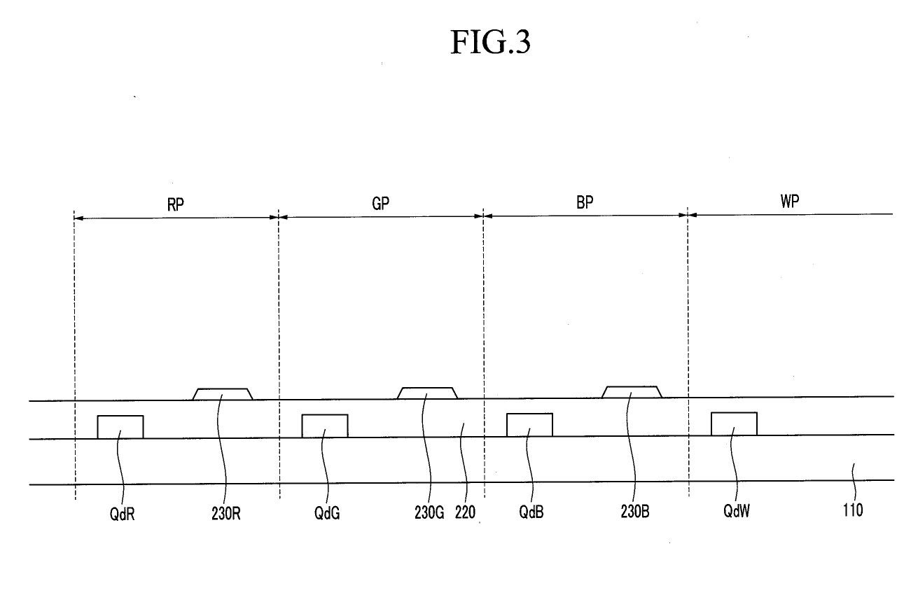

Next, a manufacturing method of the organic light emitting device shown in FIG. 2 will be described in detail with reference to FIGS. 3 to 9.

FIGS. 3 to 9 are cross-sectional views of a structure formed in intermediate steps of manufacturing the organic light emitting device of FIG. 2.

Referring to FIG. 3, a plurality of driving transistors QdR, QdG, QdB, and QdW and a thin film structure 220 are formed on a substrate 110, and then a plurality of color filters 230R, 230G, and 230B are formed.

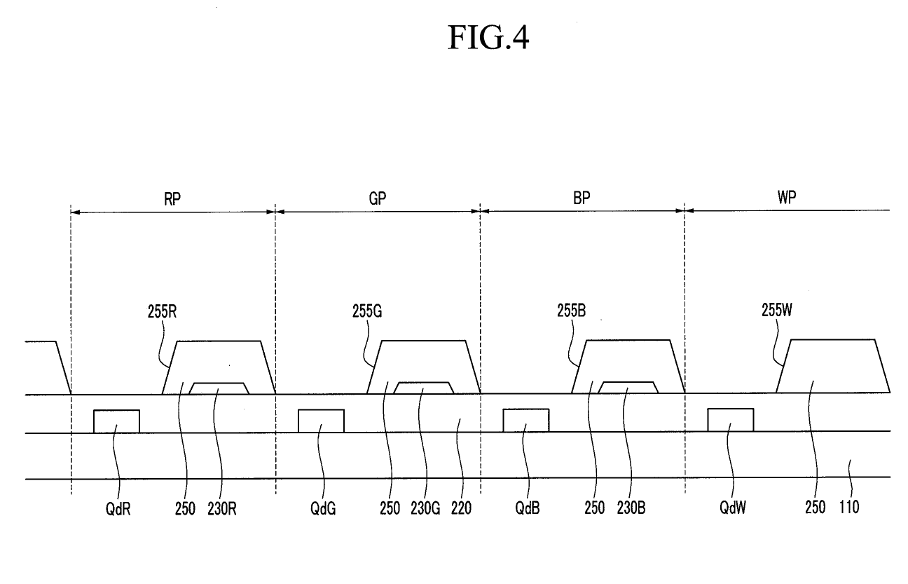

Referring to FIG. 4, an overcoat 250 made of a photosensitive organic material is coated, and then a plurality of through holes 255R, 255G, 255B, and 255W are formed on the overcoat 250 by exposing and developing the overcoat 250.

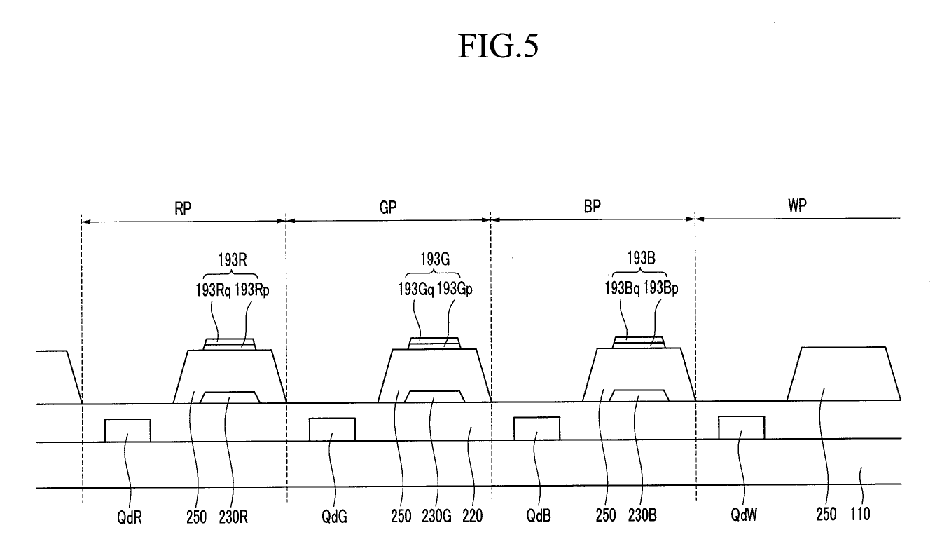

Referring to FIG. 5, transflective members 193R, 193G, and 193B with a double layer of each of conductive oxide members 193Rp, 193Gp, and 193Bp and each of transflective metal members 193Rq, 193Gq, and 193Bq are formed on the overcoat 250. They may be deposited by sputtering, and particularly, the conductive oxide members 193Rp, 193Gp, and 193Bp and the transflective metal members 193Rq, 193Gq, and 193Bq may be formed by a single photolithography step at the same time or by two separate photolithography steps.

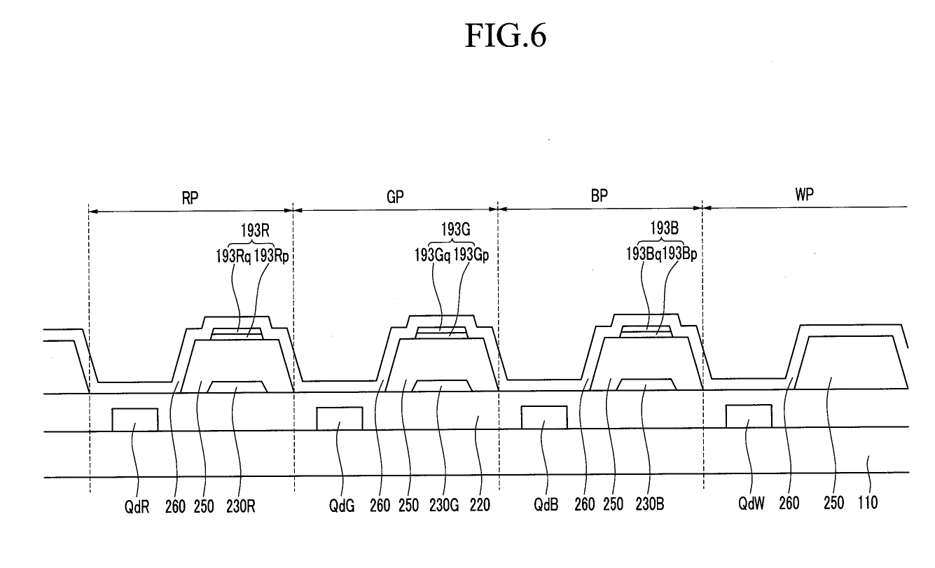

Referring to FIG. 6, an inorganic material such as silicon oxide or silicon nitride is deposited by chemical vapor deposition (CVD) to form an insulating layer 260.

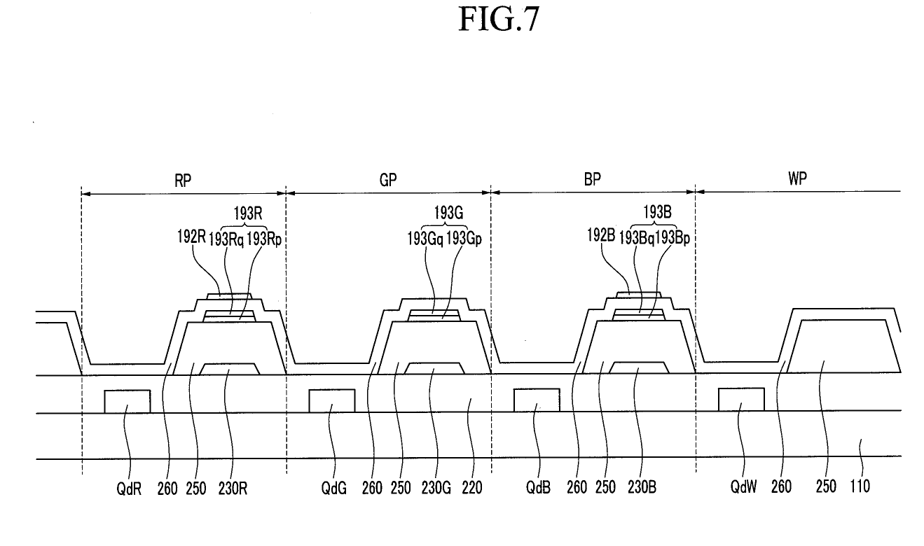

Referring to FIG. 7, a transparent conductor such as ITO or IZO is deposited on the insulating layer 260 by sputtering, and is then etched by photolithography to form a plurality of transparent electrodes 192R and 192B.

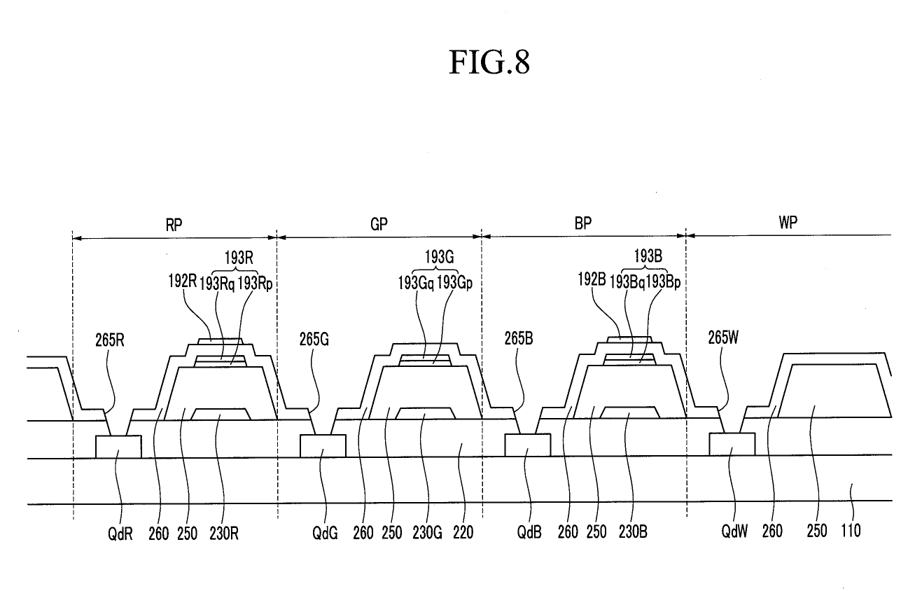

Referring to FIG. 8, the insulating layer 260 and the thin film structure 220 are etched by photolithography to form a plurality of contact holes 265R, 265G, 265B, and 265W.

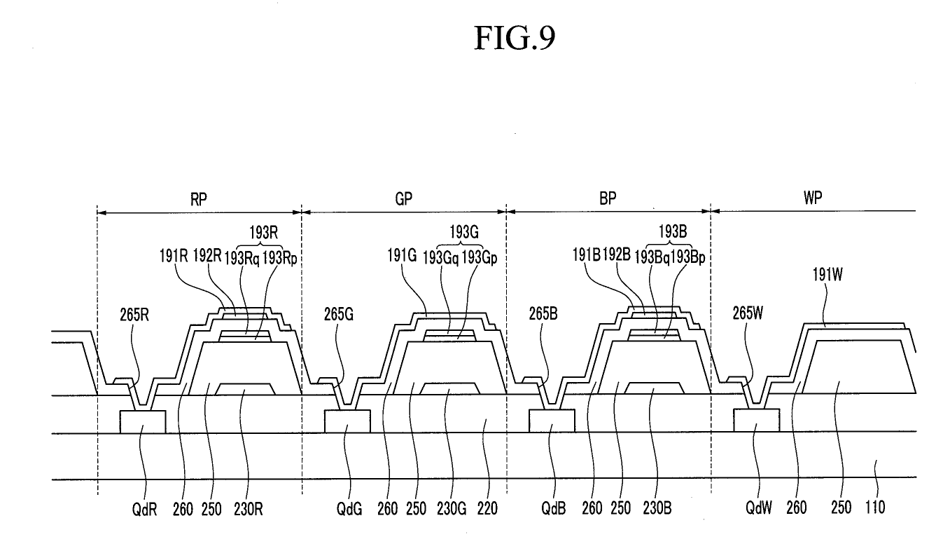

Referring to FIG. 9, a plurality of pixel electrodes 191R, 191G, 191B, and 191W are formed on the transparent electrodes 192R and 192B and the insulating layer 260.

Finally, as shown in FIG. 2, a white organic light emitting member 370 and a common electrode 270 are sequentially formed.

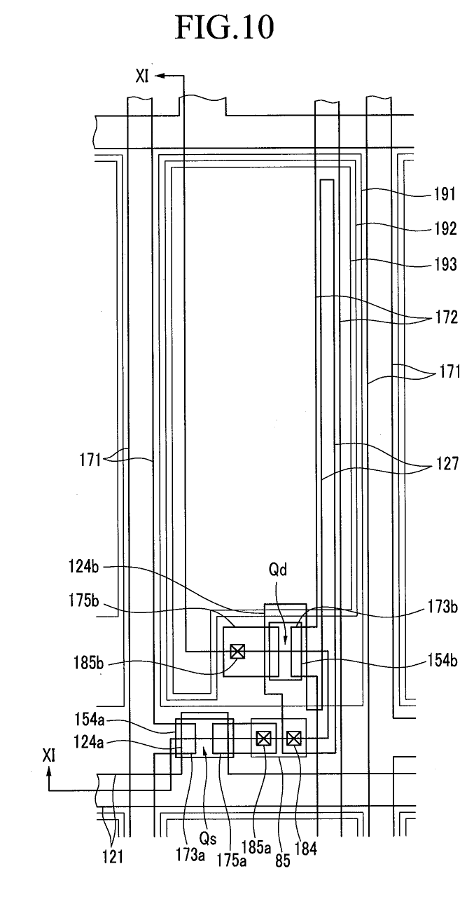

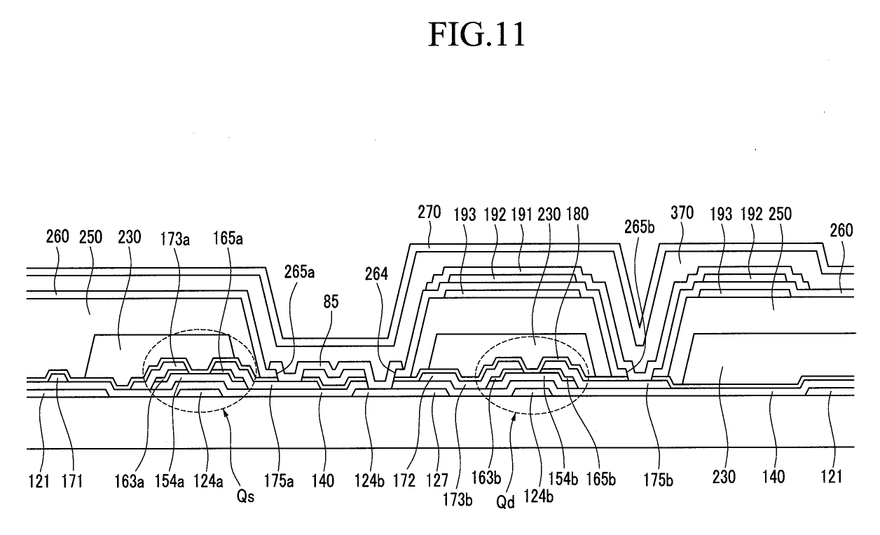

Next, an example of the structure of the red pixel or the blue pixel in the organic light emitting device shown in FIG. 2 will be described in detail with reference to FIGS. 10 and 11.

FIG. 10 is a layout view of the organic light emitting device in accordance with the exemplary embodiment of the present invention, and FIG. 11 is a cross-sectional view of the organic light emitting device taken along line XI-XI of FIG. 10.

A gate line 121 including a first control electrode 124a and a second control electrode 124b are formed on an insulation substrate 110 made of transparent glass or plastic.

The gate line 121 extends substantially in the horizontal direction, and the first control electrode 124a protrudes upwardly. The gate line 121 may include a wide end portion (not shown) for connection with another layer or an external driving circuit.

The second control electrode 124b is separated away from the gate line 121 and includes a storage electrode 127 extending in the vertical direction.

A gate insulating layer 140 made of silicon oxide or silicon nitride is formed on the gate line 121 and the second control electrode 124b.

First and second semiconductor islands 154a and 154b made of hydrogenated amorphous silicon are formed on the gate insulating layer 140. The first semiconductor island 154a is positioned on the first control electrode 124a, and the second semiconductor island 154b is positioned on the second control electrode 124b.

A pair of first ohmic contacts 163a and 165a are formed on the first semiconductor island 154a, and a pair of second ohmic contacts 163b and 165b are formed on the second semiconductor island 154b. The ohmic contacts 163a, 163b, 165a, and 165b may have an island shape, and may be made of a material such as n+ hydrogenated amorphous silicon doped with n-type impurities such as phosphorus at a high concentration.

A data line 171, a driving voltage line 172, and first and second output electrodes 175a and 175b are formed on the ohmic contacts 163a, 163b, 165a, and 165b and the gate insulating layer 140.

The data line 171 and the driving voltage line 172 extend substantially in the vertical direction to cross the gate line 121. The data line 171 includes a first input electrode 173a extending toward the first control electrode 124a, and the driving voltage line 172 includes a second input electrode 173b extending toward the second control electrode 124b.

The first and second output electrodes 175a and 175b are separated from each other and are also separated from the data line 171 and the driving voltage line 172. The first input electrode 173a and the first output electrode 175a face each other with the first control electrode 124a interposed therebetween, and the second input electrode 173b and the second output electrode 175b face each other with the second control electrode 124b interposed therebetween.

The ohmic contacts 163a, 163b, 165a, and 165b are present only between the semiconductor islands 154a and 154b at the bottom thereof, and the data line 171, the driving voltage line 172, and the output electrodes 175a and 175b at the top thereof, to reduce contact resistance. The semiconductor islands 154a and 154b have exposed portions that are not covered by the input electrodes 173a and 173b and the output electrodes 175a and 175b in addition to the portions between the input electrodes 173a and 173b and the output electrodes 175a and 175b.

The first control electrode 124a, the first input electrode 173a, and the first output electrode 175a form a switching thin film transistor (TFT) Qs together with the first semiconductor island 154a, and the second control electrode 124b, the second input electrode 173b, and the second output electrode 175b form a driving thin film transistor Qd together with the second semiconductor island 154b.

The above-described structures of the switching thin film transistor Qs, the driving thin film transistor Qd, the gate line 121, the data line 171, and the driving voltage line 172 are just one example, and there may be many examples.

A passivation layer 180 is formed on the data line 171, the driving voltage line 172, the output electrodes 175a and 175b, and the exposed semiconductor islands 154a and 154b. The passivation layer 180 may be made of an inorganic insulator such as silicon nitride or silicon oxide.

A color filter 230 is formed on the passivation layer 180, and an overcoat 250 is formed thereon.

A transflective member 193 is formed on the overcoat 250, and an insulating layer 260 is formed thereon.

Contact holes 265a and 265b exposing the output electrodes 175a and 175b are formed on the insulating layer 260 and the passivation layer 180, and a contact hole 264 exposing the second control electrode 124b is formed on the insulating layer 260, the passivation layer 180, and the gate insulating layer 140.

A transparent electrode 192 is formed on the insulating layer 260, and a pixel electrode 191 and a connecting member 85 are formed thereon.

The pixel electrode 191 is connected to the second output electrode 175b through the contact hole 265b, and the connecting member 85 is connected to the second control electrode 124b and the first output electrode 175a through the contact holes 264 and 265b.

A white organic light emitting member 370 is formed on the pixel electrode 191 and the insulating layer 260, and a common electrode 270 is formed thereon.

A barrier rib may be formed on an edge of the pixel electrode 191 and the connecting member 85 so that the white organic light emitting member 370 does not contact them.

In this way, it is possible to improve optical characteristics of the organic light emitting device and further reduce the deviation of the optical characteristics.

The present invention may be applied to various types of organic light emitting device.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting device comprising:
a thin film structure disposed on a substrate;
a first color filter disposed on the thin film structure;
a first insulating layer disposed on the first color filter;
a first transflective metal member disposed on the first insulating layer and positioned on the first color filter;
a second insulating layer disposed on the first transflective metal member;
a first transparent electrode disposed on the second insulating layer and positioned on the first transflective metal member;
a first pixel electrode disposed on the first transparent electrode;
a white organic light emitting member disposed on the first pixel electrode; and
a common electrode disposed on the white organic light emitting member.

2. The organic light emitting device of claim 1, wherein the first transflective metal member comprises silver or aluminum.

3. The organic light emitting device of claim 2, wherein the first transflective metal member has a thickness of about 50 Å to about 200 Å.

4. The organic light emitting device of claim 3, further comprising a first conductive oxide member disposed between the first insulating layer and the first transflective metal member.

5. The organic light emitting device of claim 4, wherein the first conductive oxide member comprises indium tin oxide (ITO) or indium zinc oxide (IZO).

6. The organic light emitting device of claim 5, wherein the first conductive oxide member has a thickness of about 50 Å to about 500 Å.

7. The organic light emitting device of claim 1, wherein the first transparent electrode comprises indium tin oxide (ITO) or indium zinc oxide (IZO).

8. The organic light emitting device of claim 7, wherein the first transparent electrode has a thickness of about 300 Å to about 3000 Å.

9. The organic light emitting device of claim 1, further comprising a first conductive oxide member disposed between the first insulating layer and the first transflective metal member.

10. The organic light emitting device of claim 1, further comprising:
a second color filter disposed between the thin film structure and the first insulating layer;
a second transflective metal member disposed between the first insulating layer and the second insulating layer and positioned on the second color filter; and
a second pixel electrode disposed between the second insulating layer and the white organic light emitting member, being in contact with the second insulating layer, and positioned on the first transflective metal member.

11. The organic light emitting device of claim 10, further comprising a second conductive oxide member disposed between the first insulating layer and the second transflective metal member.

12. The organic light emitting device of claim 10, further comprising
a third pixel electrode disposed between the second insulating layer and the white organic light emitting member and being in contact with the second insulating layer,
wherein a portion of the first insulating layer disposed under the third pixel electrode entirely contacts the thin film structure, and
a portion of the second insulating layer disposed under the third pixel electrode entirely contacts the first insulating layer.

13. The organic light emitting device of claim 1, wherein the first insulating layer comprises an organic material.

14. The organic light emitting device of claim 1, wherein the second insulating layer comprises an inorganic material.

15. The organic light emitting device of claim 14, wherein the second insulating layer comprises silicon oxide or silicon nitride.

16. The organic light emitting device of claim 15, wherein the second insulating layer has a thickness of about 500 Å to about 3000 Å.

17. An organic light emitting device comprising:
a substrate including a first region, a second region, and a third region;
a thin film structure disposed on the substrate;
first, second, and third color filters disposed on the thin film structure and positioned in the first, second, and third regions, respectively;
a first insulating layer disposed on the first to third color filters;
first, second, and third transflective metal members disposed on the first insulating layer and positioned in the first, second, and third regions, respectively;
a second insulating layer disposed on the first to third transflective metal members;
first and second transparent electrodes disposed on the second insulating layer and positioned in the first and second regions, respectively;
first and second pixel electrodes disposed on the first and second transparent electrodes, respectively;
a third pixel electrode disposed on the second insulating layer, positioned in the third region, and contacting the second insulating layer;
a white organic light emitting member disposed on the first to third pixel electrodes; and
a common electrode disposed on the white organic light emitting member.

18. The organic light emitting device of claim 17, wherein the first transflective metal member comprises silver or aluminum.

19. The organic light emitting device of claim 17, wherein the first insulating layer comprises an organic material and the second insulating layer comprises an inorganic material.

20. The organic light emitting device of claim 17, wherein the substrate further comprises a fourth region,
the organic light emitting device further comprises a fourth pixel electrode disposed between the second insulating layer and the white organic light emitting member and positioned in the fourth region,
the first insulating layer is in contact with the thin film structure in the fourth region, and
the second insulating layer is in contact with the fourth pixel electrode and the first insulating layer in the fourth region.

21. The organic light emitting device of claim 17, wherein the first color filter represents red, the second color filter represents blue, and the third color filter represents green.

22. A method of manufacturing an organic light emitting device, the method comprising:
forming a thin film structure on a substrate including a first region, a second region, and a third region;
forming first, second, and third color filters in the first, second, and third regions on the thin film structure, respectively;
forming a first insulating layer on the first to third color filters;
forming first, second, and third transflective metal members in the first, second, and third regions on the first insulating layer, respectively;
forming a second insulating layer on the first to third transflective metal members;
forming first and second transparent electrodes in the first and second regions on the second insulating layer, respectively;
forming a first pixel electrode on the first transparent electrode, a second pixel electrode on the second transparent electrode, and a third pixel electrode contacting the second insulating layer in the third region on the second insulating layer;
forming a white organic light emitting member on the first to third pixel electrodes; and
forming a common electrode on the white organic light emitting member.

23. The method of claim 22, wherein the first transflective metal member comprises silver or aluminum.

24. The method of claim 22, wherein the first insulating layer comprises an organic material and the second insulating layer comprises an inorganic material.

25. The method of claim 22, wherein the substrate further comprises a fourth region,
the method further comprises forming a fourth pixel electrode in the fourth region between the second insulating layer and the white organic light emitting member,
the first insulating layer is in contact with the thin film structure in the fourth region, and
the second insulating layer is in contact with the fourth pixel electrode and the first insulating layer in the fourth region.
